(19) United States
(12) Patent Application Publication
(10) Pub. No.: US 2025/0106997 A1
(43) Pub. Date: Mar. 27, 2025

(54) ELECTROLESS SEED LAYER DEPOSITION ON GLASS CORE SUBSTRATES

(71) Applicant: Intel Corporation, Santa Clara, CA (US)

(72) Inventors: Ehsan ZAMANI, Phoenix, AZ (US); Umesh PRASAD, Chandler, AZ (US); Logan MYERS, Chandler, AZ (US); Shayan KAVIANI, Phoenix, AZ (US); Darko GRUJICIC, Chandler, AZ (US); Elham TAVAKOLI, Phoenix, AZ (US); Mahdi MOHAMMADIGHALENI, Phoenix, AZ (US); Rengarajan SHANMUGAM, Tempe, AZ (US); Rachel Guia GIRON, Mesa, AZ (US); Srinivas Venkata Ramanuja PIETAMBARAM, Chandler, AZ (US); Gang DUAN, Chandler, AZ (US)

(21) Appl. No.: 18/373,088

(22) Filed: Sep. 26, 2023

(51) Int. Cl. H05K 1/11; H01L 23/15; H01L 23/498; H05K 1/03

(52) U.S. Cl. CPC H05K 1/116; H05K 1/0306; H01L 23/15; H01L 23/49822; H05K 2201/0179; H05K 2201/0209; H05K 2201/032; H05K 2201/09581

(57) ABSTRACT

Embodiments disclosed herein include glass cores with through glass vias (TGVs). In an embodiment, an apparatus comprises a substrate that is a solid glass layer. In an embodiment, an opening is provided through a thickness of the substrate, and a liner with a first surface is on a sidewall of the opening and a second surface is facing away from the sidewall of the opening. In an embodiment, the liner comprises a matrix, and filler particles in the matrix. In an embodiment, a plurality of cavities are provided into the second surface of the liner. In an embodiment, a via is in the opening, where the via is electrically conductive.

### BACKGROUND

As semiconductor packaging architectures continue towards more complex and more compact systems, new material solutions may be used to enable such architectures. One promising candidate for use in packaging substrates is a glass core layer. In such substrates, a glass core is sandwiched between overlying and underlying buildup layers. Electrically conductive vias are provided through the glass core in order to provide electrical coupling between the overlying and underlying buildup layers. Glass cores are beneficial because they can provide high density vias. Glass is also a high modulus material, which provides desirable stiffness to the overall package substrate.

Forming via openings through the glass core typically uses a laser assisted etching process. This results in tapered sidewalls that are difficult to plate with traditional plating processes, such as physical vapor deposition (PVD). For high aspect ratio openings, this leads to portions of the sidewalls that are shadowed or otherwise not covered by the deposited metal. Subsequent electroplating using a non-continuous seed layer may result in the formation of voids or other defects in the electrically conductive via.

### BRIEF DESCRIPTION OF THE DRAWINGS

FIG. 1A is a cross-sectional illustration of a glass core with a via opening, in accordance with an embodiment.

FIG. 1B is a cross-sectional illustration of the glass core with a plated seed layer that is non-continuous over surfaces of the via opening, in accordance with an embodiment.

FIG. 1C is a cross-sectional illustration of the glass core after electroplating to form a via with a void, in accordance with an embodiment.

FIG. 2A is a cross-sectional illustration of a glass core with a liner and a seed layer deposited with an electroless process, in accordance with an embodiment.

FIG. 2B is a cross-sectional illustration of the glass core after an electrically conductive via is plated over the seed layer, in accordance with an embodiment.

FIG. 3A is a cross-sectional illustration of a portion of a via opening with a liner that includes filler particles, in accordance with an embodiment.

FIG. 3B is a cross-sectional illustration of the portion of the via opening after surface exposed loose fillers are removed to form cavities in the liner, in accordance with an embodiment.

FIG. 3C is a cross-sectional illustration of the portion of the via opening after a first pretreatment process that attaches cationic surfactants to fillers and nonionic surfactants to the rest of the liner, in accordance with an embodiment.

FIG. 3D is a cross-sectional illustration of the portion of the via opening after anionic surfactants are attached to the cationic surfactant sites during a second pretreatment, in accordance with an embodiment.

FIG. 3E is a cross-sectional illustration of the portion of the via opening after palladium is attached to the anionic surfactant sites, in accordance with an embodiment.

FIG. 4A is a cross-sectional illustration of a glass core, in accordance with an embodiment.

FIG. 4B is a cross-sectional illustration of the glass core after a via opening is formed through a thickness of the glass core, in accordance with an embodiment.

FIG. 4C is a cross-sectional illustration of the glass core after a liner is applied over sidewalls of the via opening, in accordance with an embodiment.

FIG. 4D is a cross-sectional illustration of the glass core after a self-assembled monolayer (SAM) is applied over the liner, in accordance with an embodiment.

FIG. 4E is a cross-sectional illustration of the glass core after a seed layer is applied over the SAM with an electroless process, in accordance with an embodiment.

FIG. 4F is a cross-sectional illustration of the glass core after an electrically conductive via is plated in the via opening, in accordance with an embodiment.

FIG. 5A is a cross-sectional illustration of a liner over a glass surface, in accordance with an embodiment.

FIG. 5B is a cross-sectional illustration of the liner after hydrophilization, in accordance with an embodiment.

FIG. 5C is a cross-sectional illustration of the liner showing the SAM being attached to the liner by chemical vapor deposition (CVD), in accordance with an embodiment.

FIG. 5D is a cross-sectional illustration of the liner after the SAM is attached to the liner, in accordance with an embodiment.

FIG. 5E is a cross-sectional illustration of the liner after the seed layer is provided over the SAM, in accordance with an embodiment.

FIG. 6A is a cross-sectional illustration of a negatively charged glass core, in accordance with an embodiment.

FIG. 6B is a cross-sectional illustration of the glass core after a positively charged liner is applied, in accordance with an embodiment.

FIG. 6C is a cross-sectional illustration of the glass core after palladium is adsorbed to the liner, in accordance with an embodiment.

FIG. 6D is a cross-sectional illustration of the glass core after a seed layer is formed over the liner with an electroless process, in accordance with an embodiment.

FIG. 6E is a cross-sectional illustration of the glass core after a via is plated over the seed layer, in accordance with an embodiment.

FIG. 7 is a cross-sectional illustration of a package substrate with a glass core and electroless seed layer, in accordance with an embodiment.

FIG. 8 is a cross-sectional illustration of an electronic system with a package substrate that includes a glass core with an electroless seed layer, in accordance with an embodiment.

FIG. 9 is a schematic of a computing device built in accordance with an embodiment.

### EMBODIMENTS OF THE PRESENT DISCLOSURE

Described herein are electronic systems, and more particularly, electroless copper seed layers for use in via plating in glass cores, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

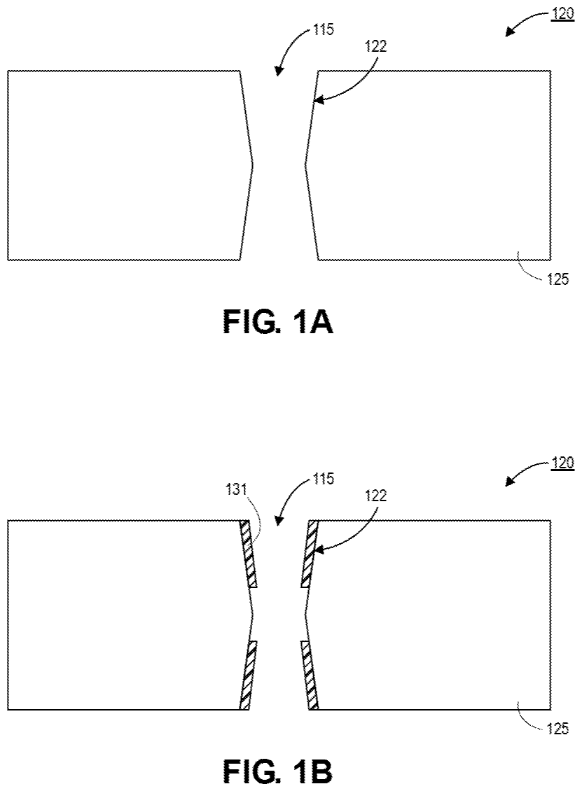

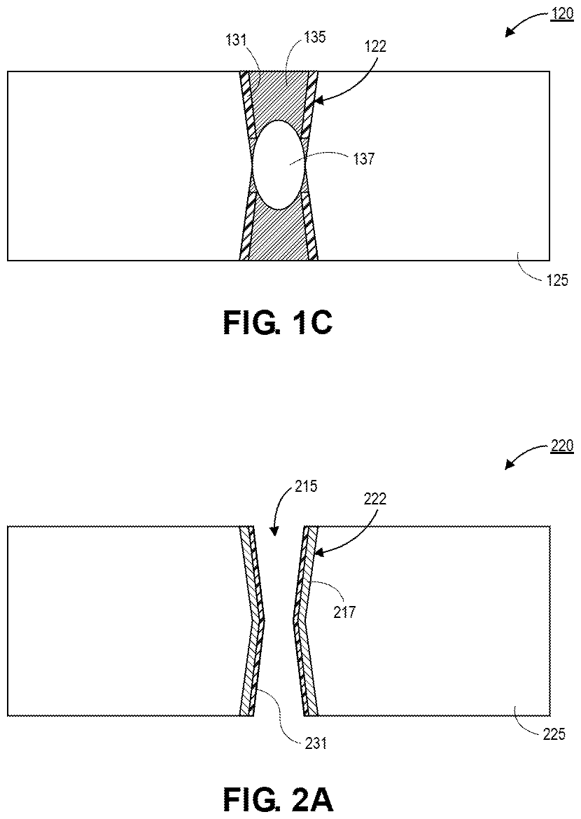

As noted above, glass cores for package substrates are of an increasing interest in the electronics packaging industry. However, the fabrication and integration processes used to integrate a glass core into a package substrate are still in their early stages of development. One particular issue that has arisen is the formation of fully filled high aspect ratio vias through a thickness of the glass core. High aspect ratio vias may refer to vias with aspect ratios (height:width) that are approximately 5:1 or greater, 10:1 or greater, or 20:1 or greater. One problem is that the deposition of the seed layer does not provide complete coverage of the sidewalls of the via openings. Typically, a physical vapor deposition (PVD) process is used to form the seed layer. PVD processes have difficulty plating the sidewall portions towards the middle (in the Z-direction) of the via opening. As such voids and other defects are commonly present. An example of this defect generation is shown in FIGS. 1A-1C.

Referring now to FIG. 1A, a cross-sectional illustration of a glass core 120 is shown, in accordance with an embodiment. The glass core 120 may comprise a solid glass layer 125. The glass layer 125 may have a thickness that is between approximately 50 μm and approximately 2,000 μm. A via opening 115 may be provided through a thickness of the glass layer 125. The via opening 115 may be a high aspect ratio structure.

The via opening 115 may be formed with any suitable process. For example, a laser assisted etching process may be used. Such a process includes exposing the glass layer 125 to a laser. The laser exposure modifies the structure of the glass material and renders the exposed areas more susceptible to a wet etching chemistry. The use of a laser assisted etching process may result in sidewalls 122 that are tapered or otherwise sloped. When a double sided laser exposure process is used (i.e., laser exposure of both the top surface and the bottom surface of the glass layer 125), the via opening 115 may have an hourglass shaped profile. If a single sided laser exposure process is used, the via opening 115 may have a single taper with a wider opening on the exposed surface and a narrower opening on the non-exposed surface.

Referring now to FIG. 1B, a cross-sectional illustration of the glass core 120 after a seed layer 131 is applied to the via opening 115 is shown. The seed layer 131 is typically deposited with a PVD process. This is because the glass layer 125 is insulating, and an electroless process is not currently available. In an embodiment, the seed layer 131 is provided along the sidewalls 122. As shown, the seed layer 131 is non-continuous over the entire height of the sidewalls 122. For example, a gap in the seed layer 131 may be present around a middle (in the Z-direction) of the via opening 115. This can be due, at least in part to the high aspect ratio of the via opening 115, and the slope of the sidewalls 122. The presence of the gap in the seed layer 131 may result in plating defects, as will be shown in FIG. 1C.

Referring now to FIG. 1C, a cross-sectional illustration of the glass core 120 after a via 135 is plated in the via opening 115. The via 135 may be plated with an electroplating process using the seed layer 131 to initiate the plating. Due to the non-continuous seed layer 131, the via 135 may be plated up so that a void 137 is generated in the via 135. The void 137 will increase the resistance of the via 135 and reduces electrical performance.

Accordingly, embodiments disclosed herein provide enhanced processes for seed layer generation. The embodiments disclosed herein allow for a continuous (or near continuous) seed layer to be formed over the sidewalls of the via openings. This then allows for improved plating of the bulk of the via, and electrical performance of the glass core is improved. More particularly, the seed layer deposition processes disclosed herein rely on electroless deposition processes. An electroless process allows for high aspect ratio features to be fully plated, and the process is not limited by line of sight.

In one embodiment, the seed layer is plated over a liner. The liner may have filler particles. Before the seed layer is plated, the liner is treated in order to remove particles from the surface of the liner to form cavities. Ionic and anionic surfactants are then applied in order to provide sites for palladium adsorption. The palladium serves as the catalyst in order to electrolessly deposit a copper seed layer over the liner.

In another embodiment, a self-assembled monolayer (SAM) is applied over the liner. For example, the liner may be treated with a plasma to generate oxygen-hydrogen terminations. The SAM molecules may then be deposited (e.g., with a chemical vapor deposition (CVD) process). The SAM has reactive groups that can be directly activated by exposure to a PdCl₂ solution to form a palladium terminated surface to enable electroless copper seed layer deposition.

In another embodiment, a cationic liner can be applied to the negatively charged glass core. For example, the liner may include a polyethylenimine (PEI) material. The cationic liner may have nitrogen and hydrogen terminations that can react with palladium so that the palladium adsorbs to the liner. The palladium can then be used to electrolessly plate the copper seed layer.

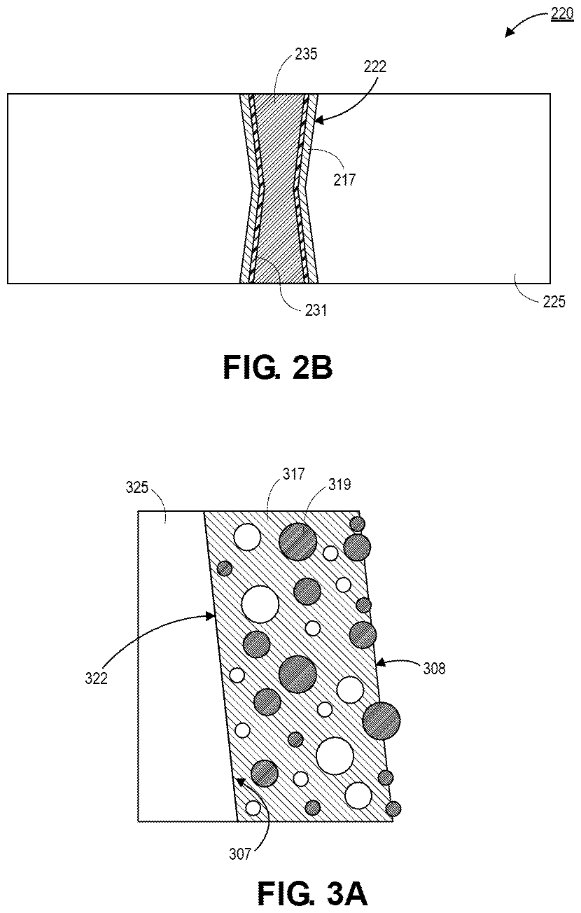

Referring now to FIG. 2A, a cross-sectional illustration of a glass core 220 is shown, in accordance with an embodiment. In an embodiment, the glass core 220 may comprise a solid glass layer 225. That is, the glass core 220 is distinct from a typical organic dielectric core that may have glass fiber reinforcements. The glass layer 225 may be a solid material with an amorphous crystal structure. More particularly, the glass layer 225 may be any suitable glass formulation that has the necessary mechanical robustness and compatibility with semiconductor packaging manufacturing and assembly processes. For example, the glass layer 225 may comprise aluminosilicate glass, borosilicate glass, alumino-borosilicate glass, silica, fused silica, or the like. In some embodiments, the glass core 220 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, and Zn. More generally, the glass layer 225 may comprise silicon and oxygen, as well as any one or more of aluminum, boron, magnesium, calcium, barium, tin, sodium, potassium, strontium, phosphorus, zirconium, lithium, titanium, and zinc. In an embodiment, the glass layer 225 may comprise at least 23 percent silicon (by weight) and at least 26 percent oxygen (by weight). In some embodiments, the glass layer 225 may further comprise at least 5 percent aluminum (by weight).

In an embodiment, the glass layer 225 may have a rectangular shape when viewed in a plan view from above. Though other shapes may also be used. A thickness of the glass layer 225 may be between approximately 50 μm and approximately 2,000 μm. Though, a thinner or thicker glass layer 225 may also be used in some embodiments. As used herein, “approximately” may refer to a range of values within ten percent of the stated value. For example, approximately 100 μm may refer to a range between 90 μm and 110 μm.

In an embodiment, a via opening 215 may be formed through a thickness of the glass layer 225. The via opening 215 may include sidewalls 222. In an embodiment, the sidewalls 222 may be tapered or otherwise sloped. Though, in other embodiments, the sidewalls 222 may be substantially vertical (e.g., within approximately 10° of being orthogonal to the top surface of the glass layer 225). In the illustrated embodiment, the via opening 215 has an hourglass shaped cross-section. Other embodiments may include a via opening 215 with a single taper.

In an embodiment, the sidewalls 222 may be covered by a liner 217. The liner 217 may be an organic material. For example, the liner 217 may comprise a polymeric material. As will be described in greater detail below, the liner 217 may be a composite material that includes a matrix with fillers distributed within the matrix. The fillers may be inorganic filler materials, such as glass.

In an embodiment, a seed layer 231 may be applied over the liner 217. The seed layer 231 may be deposited with an electroless deposition process. As such, the seed layer 231 may comprise copper and a catalyst element, such as palladium. The process for adsorbing the catalyst element to the liner 217 in order to enable electroless plating is described in greater detail below. In contrast to the illustrations in FIGS. 1A-1C, the seed layer 231 is substantially continuous across the height of the liner 217. This can be attributable to the use of an electroless process as opposed to a line of sight process, such as PVD. Improved plating uniformity of the seed layer 231 is provided even when the via opening 215 is a high aspect ratio structure and/or when the sidewalls 222 are sloped. As used herein, a “substantially continuous” layer may be a layer that covers at least 70% or more of an underlying layer, at least 90% or more of an underlying layer, or at least 99% or more of an underlying layer.

Referring now to FIG. 2B, a cross-sectional illustration of the glass core 220 after a via 235 is plated is shown, in accordance with an embodiment. In an embodiment, the via 235 may be an electrically conductive material, such as copper, an alloy comprising copper, or any other suitable metallic material with a suitably high electrical conductivity. The via 235 may be a bulk material that is substantially without voids. The voidless structure is enabled, at least in part, by the continuous seed layer 231. In some embodiments, a distinct interface may be visible between the seed layer 231 and the bulk material of the via 235. In other embodiments, the seed layer 231 and the via 235 may have a substantially seamless interface.

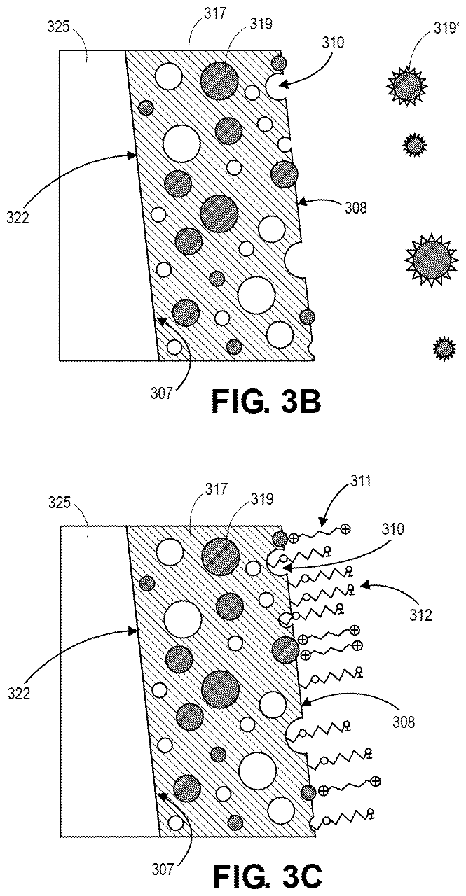

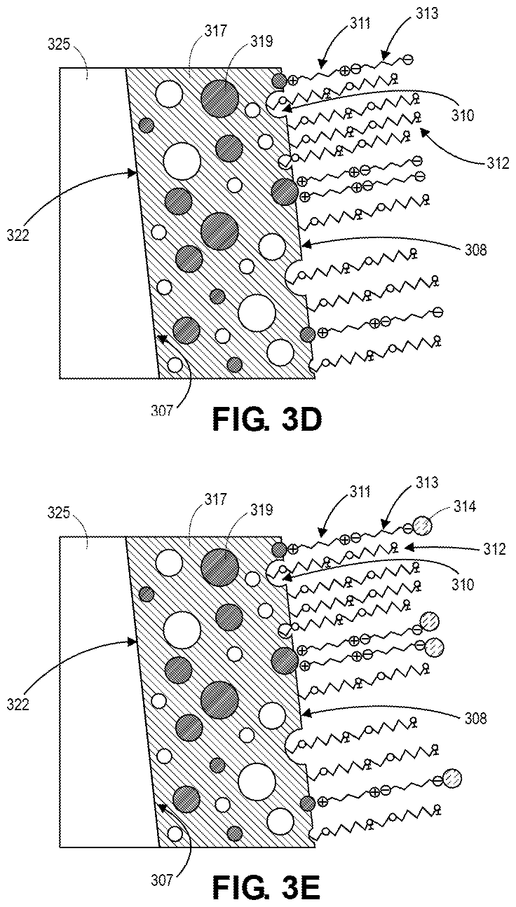

Referring now to FIGS. 3A-3E, a series of cross-sectional illustrations depicting a process for treating a surface of a liner 317 in order to prepare for electroless deposition of a seed layer is shown, in accordance with an embodiment. For example, the liner 317 may be similar to the liner 217 described in FIGS. 2A and 2B. The views in FIGS. 3A-3E are zoomed in on the liner 317 as opposed to showing the larger structure of the glass core.

Referring now to FIG. 3A, a cross-sectional illustration of a portion of glass layer 325 is shown, in accordance with an embodiment. The glass layer 325 may have a sidewall 322. For example, the sidewall 322 may be part of a via opening that passes through a thickness of the glass layer 325. The sidewall 322 may be sloped. In other embodiments, the sidewall 322 may be substantially vertical.

In an embodiment, a liner 317 is provided over the sidewall 322 of the glass layer 325. The liner 317 may have a first surface 307 that interfaces with the sidewall 322 and a second surface 308 that faces away from the glass layer 325. The liner 317 may be a composite material. For example, the liner 317 may include a matrix material that is filled with a plurality of filler particles 319. The matrix material may be an organic dielectric material. In one instance, the matrix material is a polymeric material. The filler particles 319 may comprise an inorganic dielectric material. For example, the filler particles 319 may comprise glass or the like. In an embodiment, a volume percentage of the filler particles 319 in the liner 317 may be up to approximately 25%, up to approximately 50%, or up to approximately 80%.

In an embodiment, the filler particles 319 may have any suitable shapes and dimensions. In the illustration of FIG. 3A, the filler particles 319 are substantially circular. Though, oblong shapes (e.g., oval, elongated fibers, etc.), polygonal shapes (e.g., square, rectangular, etc.), and/or irregular shapes may also be present in some embodiments. The filler particles 319 may have an average diameter or width that is between approximately 50 nm and approximately 5 μm. Though, larger or smaller filler particles 319 may be present in some embodiments.

In an embodiment, the second surface 308 may include filler particles 319. For example, filler particles 319 may extend past the second surface 308 into the volume of the via opening. The amount of the second surface 308 covered by filler particles 319 may be dependent on the volume percentage of the filler particles 319 in the liner 317. In some instances, up to approximately 20% of the second surface 308 is covered by filler particles 319, up to approximately 50% of the second surface 308 is covered by filler particles 319, or up to approximately 80% of the second surface 308 is covered by filler particles 319.

Referring now to FIG. 3B, a cross-sectional illustration of the glass layer 325 after a treatment of the second surface 308 is performed is shown, in accordance with an embodiment. In an embodiment, the treatment is a cleaning process that removes at least some of the exposed filler particles 319. The treatment process may be an alkaline cleaning process in some instances. A dispersed surfactant surrounds and releases filler particles 319′ from the liner 317. Removal of filler particles 319′ results in the formation of cavities 310 into the second surface 308. The cavities 310 may have a circular segment shape in some embodiments (e.g., when the filler particles 319 are substantially circular). Though, cavities 310 may also have other shapes. The cavities 310 may have openings into the second surface 308 with a width between approximately 20 nm and approximately 5 μm, depending on the size of the filler particles 319. The surface of the cavities 310 may have a circular segment shape when the filler particles 319 are substantially circular. In such embodiments, the arc of the circular segment shape is part of a circle that has a diameter that is within approximately 50% of an average diameter of the filler particles 319. In an embodiment, the cavities 310 can function as additional anchoring points without significantly increasing the observed roughness of the liner 317.

Referring now to FIG. 3C, a cross-sectional illustration of the glass layer 325 after a first surface treatment is shown, in accordance with an embodiment. In an embodiment, the first surface treatment may include applying a cationic surfactant 311 and a nonionic surfactant 312 to the second surface 308. The cationic surfactant 311 is attracted to the filler particles 319 exposed at the surface of the liner 317. For example, the filler particles 319 may be negatively charged. The nonionic surfactant 312 may be attracted to the matrix material of the liner 317 at the second surface 308 and within the cavities 310. The nonionic surfactant 312 may include non-charged terminations, such as OH terminations.

Referring now to FIG. 3D, a cross-sectional illustration of the glass layer 325 after a second surface treatment is shown, in accordance with an embodiment. In an embodiment, the second treatment may include applying an anionic surfactant 313 and more of the nonionic surfactant 312. The anionic surfactant 313 attaches to the cationic surfactant 311 (with an electrostatic coupling). This provides a negative surface charge to the liner 317, which will allow for adsorption of a catalyst.

Referring now to FIG. 3E, a cross-sectional illustration of the glass layer 325 after the catalyst 314 is applied is shown, in accordance with an embodiment. In an embodiment, the catalyst 314 may be a positively charged molecule or element that is electrostatically attracted to the negative anionic surfactant 313 sites. In some embodiments, the catalyst 314 may be palladium based. For example, the catalyst 314 may comprise Pd²⁺.

After the catalyst 314 is provided on the liner 317, a seed layer (e.g., comprising copper) can be electrolessly deposited over the liner 317. The seed layer may comprise both copper and palladium in some embodiments. Further, the seed layer has a strong adhesion to the liner 317. This is due, at least in part, to the presence of the surfactant layers over the liner 317, and improved bonding strength can be enabled due to the cavities 310. That is, the cavities 310 can function as anchoring points in order to strengthen the bond between the seed layer and the liner 317.

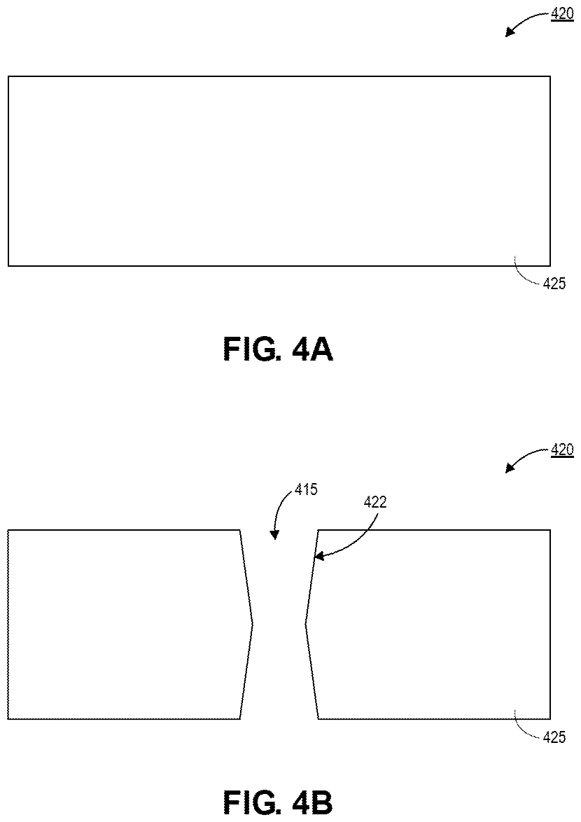

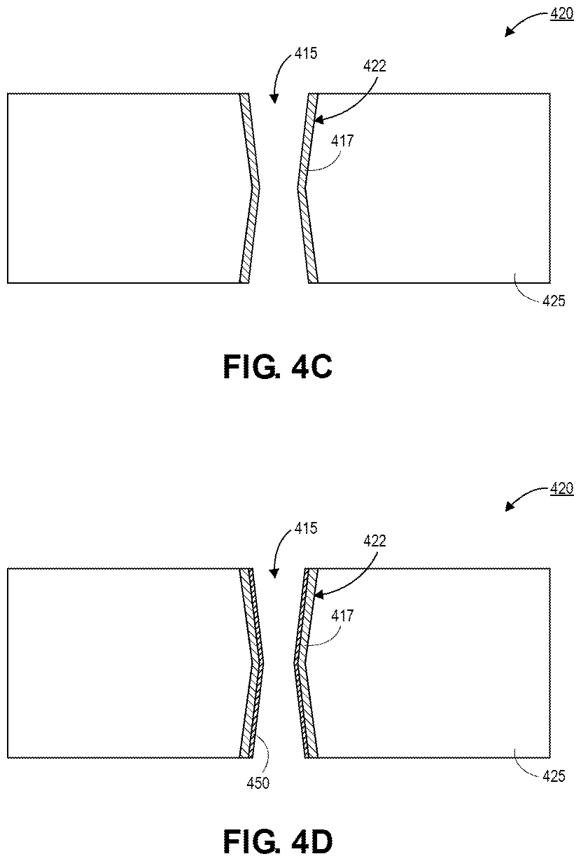

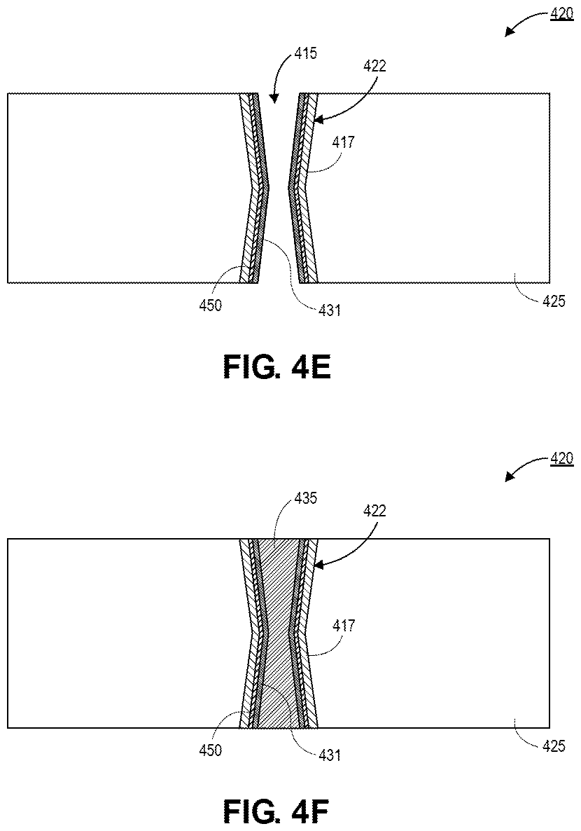

Referring now to FIGS. 4A-4F, a series of cross-sectional illustrations depicting a process for forming vias 435 through a glass core 420 using an electroless seed layer 431 is shown, in accordance with an embodiment. In some embodiments, the seed layer 431 is separated from the liner 417 by a SAM 450.

Referring now to FIG. 4A, a cross-sectional illustration of a glass core 420 is shown, in accordance with an embodiment. The glass core 420 may comprise a glass layer 425. The glass layer 425 may be similar in composition and structure to any of the glass layers described in greater detail herein.

Referring now to FIG. 4B, a cross-sectional illustration of the glass core 420 after a via opening 415 is formed through the glass layer 425 is shown, in accordance with an embodiment. The via opening 415 may be a high aspect ratio structure. The via opening 415 may have sidewalls 422 that are sloped or tapered. In the illustrated embodiment, the via opening 415 has an hourglass shaped cross-section. Though, embodiments may include via openings 415 with differently shaped cross sections as well.

Referring now to FIG. 4C, a cross-sectional illustration of the glass core 420 after a liner 417 is provided over the sidewalls 422 of the via opening 415 is shown, in accordance with an embodiment. In an embodiment, the liner 417 may be an organic dielectric material. For example, the liner 417 may be a polymeric material in some embodiments. The liner may have a thickness that is between approximately 1 μm and approximately 20 μm. Though, thicker or thinner liners 417 may be used in other embodiments.

Referring now to FIG. 4D, a cross-sectional illustration of the glass core 420 after a SAM 450 is applied is shown, in accordance with an embodiment. The SAM 450 may be applied after the liner 417 is treated (e.g., with a plasma). The SAM 450 may be introduced to the liner 417 through a CVD process. A more thorough explanation of the SAM 450 application is described in greater detail below.

Referring now to FIG. 4E, a cross-sectional illustration of the glass core 420 after a seed layer 431 is applied over the SAM 450 is shown, in accordance with an embodiment. The seed layer 431 may be applied with an electroless deposition process. For example, a catalyst (e.g., palladium) can be incorporated with the SAM 450 in order to initiate the autocatalytic reaction used to plate the copper of the seed layer 431. In some instances, the seed layer 431 may be considered as comprising both copper and palladium.

Referring now to FIG. 4F, a cross-sectional illustration of the glass core 420 after a via 435 is plated in the via opening 415 is shown, in accordance with an embodiment. In an embodiment, the via 435 is an electrically conductive material, such as copper, an alloy of copper, or any other suitable metallic material. The via 435 may be plated up from the seed layer 431 using an electroplating process. Since the seed layer 431 is substantially continuous over the underlying layers, the via 435 will generally plate up without any defects or voids. Accordingly, improved electrical performance is provided for the glass core 420, even when the via 435 is a high aspect ratio structure.

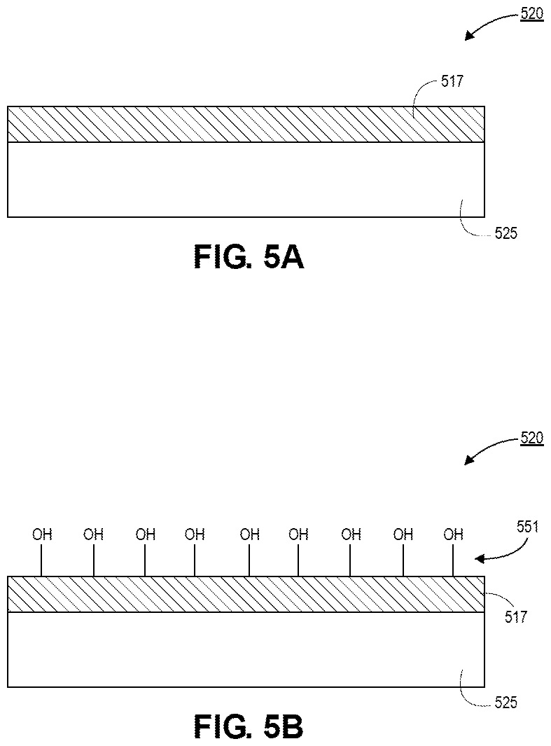

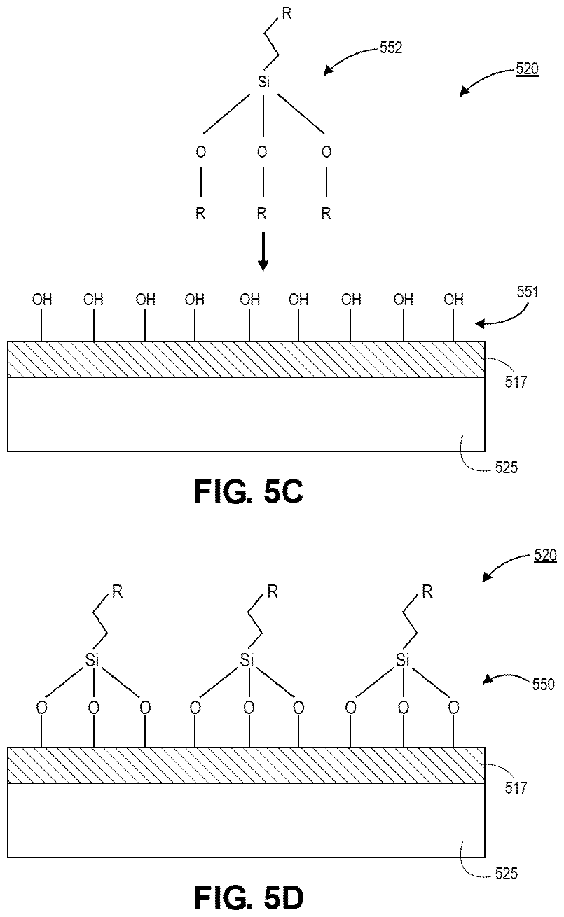

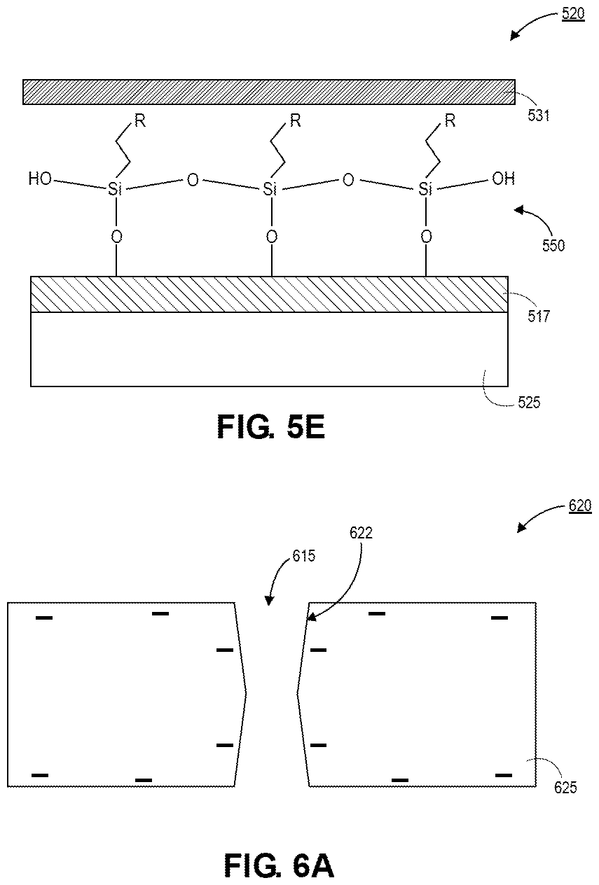

Referring now to FIGS. 5A-5E, a series of cross-sectional illustrations depicting a process for forming a SAM 550 and a seed layer 531 over a liner 517 is shown, in accordance with an embodiment.

Referring now to FIG. 5A, a cross-sectional illustration of a glass core 520 is shown, in accordance with an embodiment. The glass core 520 may comprise a glass layer 525. A liner 517 may be provided over a surface of the glass layer 525. In the illustrated embodiment, the liner 517 is above a top surface of the glass layer 525. Though, it is to be appreciated that the liner 517 may be provided over sidewalls of an opening through the glass layer 525, similar to the liner structures described in greater detail above. The liner 517 may be any suitable liner material, such as an organic dielectric. For example, the liner 517 may comprise a polymeric material.

Referring now to FIG. 5B, a cross-sectional illustration of the glass core 520 after the liner 517 is treated is shown, in accordance with an embodiment. The treatment may be a plasma treatment. For example, an O₂ plasma treatment may be used as a hydrophilization process on the liner 517. The treatment may result in terminations 551 being generated on the surface of the liner 517. For example, the terminations 551 may be —OH terminations.

Referring now to FIG. 5C, a cross-sectional illustration of the glass core 520 during application of a SAM molecule 552 is shown, in accordance with an embodiment. In an embodiment, the SAM molecule 552 may include oxygen, silicon, and carbon. Reactive groups R may also be included in the SAM molecule 552. The reactive groups R may include one or more of —SH, —SO₃H, —N₃, —NH₂, —CN, —OCH₃, —COOCH₃, and —COOH. In an embodiment, the SAM molecule 552 may be applied to the liner 517 with a CVD process or a solution-based process.

Referring now to FIG. 5D, a cross-sectional illustration of the glass core 520 after the SAM molecules 552 have reacted with the terminations 551 in order to form the SAM 550 is shown, in accordance with an embodiment. For example, the SAM 550 may comprise oxygen, silicon, carbon, and reactive groups R. In an embodiment, the reactive groups R can be directly activated by exposure to a palladium containing solution in order to form palladium terminated surfaces to enable the subsequent electroless deposition. For example, the palladium containing solution may comprise palladium and chlorine (e.g., PdCl₂).

Referring now to FIG. 5E, a cross-sectional illustration of the glass core 520 after the seed layer 531 is applied over the SAM 550 is shown, in accordance with an embodiment. In an embodiment, the seed layer 531 may be applied with an electroless process using the palladium terminated SAM 550 to initiate the reaction. In some instances, the SAM 550 application and the electroless seed layer 531 deposition can be applied in the same processing tool. The SAM 550 helps to improve adhesion of the seed layer 531 to the liner 517, and provides function groups to coordinate palladium adsorption needed for electroless copper seed layer 531 formation.

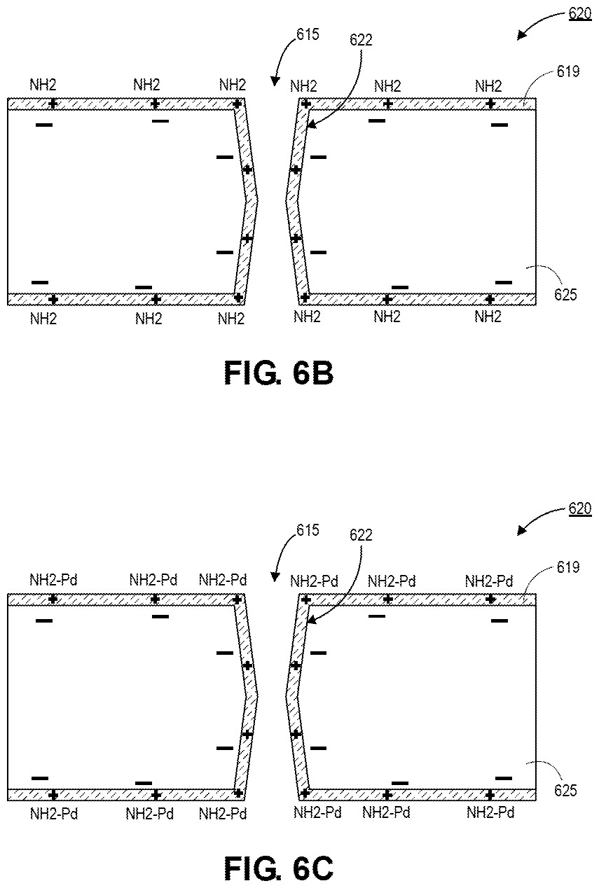

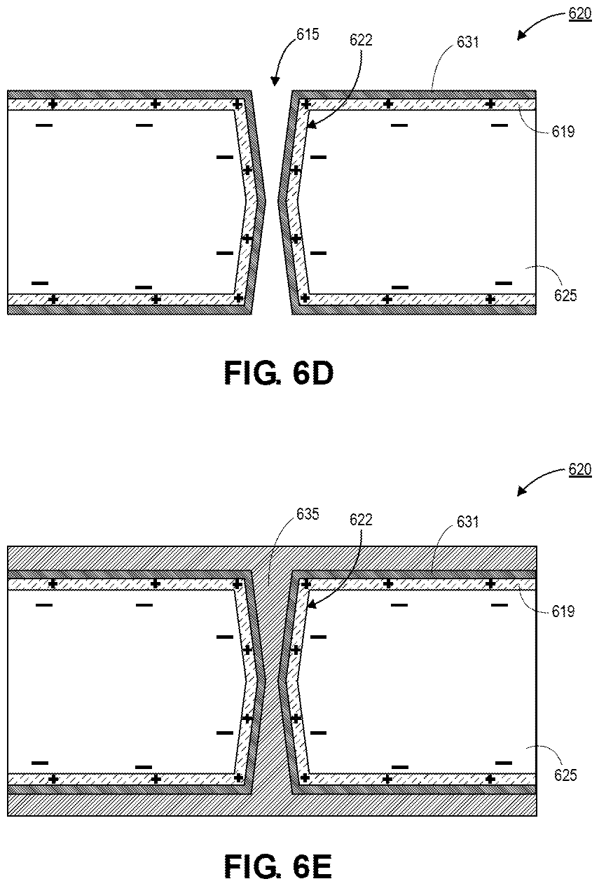

Referring now to FIGS. 6A-6E, a series of cross-sectional illustrations depicting a process for forming a glass core 620 with a via 635 formed from an electroless seed layer 631 is shown, in accordance with an embodiment.

Referring now to FIG. 6A, a cross-sectional illustration of a glass core 620 is shown, in accordance with an embodiment. In an embodiment, the glass core 620 comprises a glass layer 625. The glass layer 625 may be similar in composition and structure to any of the glass layers described in greater detail herein. In an embodiment, a via opening 615 is provided through a thickness of the glass layer 625. The via opening 615 may have an hourglass shaped cross-section or any other cross-sectional shape. For example, sidewalls 622 of the via opening 615 may be sloped or tapered in some embodiments.

In an embodiment, the glass layer 625 may be generally negatively charged. More particularly, the surface charge of the glass layer 625 is typically negative. This negative charge is indicated in FIG. 6A through the use of negative (−) symbols placed proximate to the surfaces of the glass layer 625, including the sidewalls 622 of the via opening 615.

Referring now to FIG. 6B, a cross-sectional illustration of the glass core 620 after a liner 619 is applied over surfaces of the glass layer 625 is shown, in accordance with an embodiment. In an embodiment, the liner 619 may have a cationic surface charge (as indicated by the positive (+) symbol in the liner 619). Accordingly, the liner 619 may be attracted to the negatively charged glass layer 625 through the electrostatic force. As such, adhesion between the two layers is improved. The liner 619 may be applied with any suitable process, such as dip coating, spin coating, or the like. In an embodiment, the liner 619 may be any suitable dielectric material.

In one embodiment, the liner 619 may comprise polyethylenimine (PEI). Using PEI may be advantageous due to existing nitrogen containing terminations (shown as NH₂ terminations in FIG. 6B). For example, the terminations may be linear, branched, and/or dendrimer. The NH₂ terminations may be beneficial for interacting with palladium containing molecules in order to provide a catalyst layer for subsequent seed layer deposition.

Referring now to FIG. 6C, a cross-sectional illustration of the glass core 620 after a catalyst is applied to the liner 619 is shown, in accordance with an embodiment. In an embodiment, the catalyst may comprise palladium. For example, Pd²⁺ adsorption through polymer-metal complex interactions and reduction of Pd²⁺ may result in palladium bonding to the nitrogen containing termination (shown as NH₂—Pd in FIG. 6C). The use of a metal-polymer complex can be beneficial due to the enhancement of the peel strength between the liner 619 and the subsequently plated seed layer 631.

Referring now to FIG. 6D, a cross-sectional illustration of the glass core 620 after the seed layer 631 is deposited is shown, in accordance with an embodiment. In an embodiment, the seed layer 631 may be plated with an electroless plating process. The seed layer 631 may comprise copper. In other embodiments, the seed layer 631 may comprise copper and palladium. Though, other metallic elements may also be incorporated into the seed layer 631 in some embodiments.

Referring now to FIG. 6E, a cross-sectional illustration of the glass core 620 after a via 635 is plated in the via opening 615 is shown, in accordance with an embodiment. In an embodiment, the via 635 may be plated with an electroplating process that uses the seed layer 631 to initiate the plating. The via 635 may comprise copper, an alloy comprising copper, or any other suitable metallic material. Due to the good coverage of the seed layer 631 over the liner 619 in the via opening 615, the via 635 will be substantially free of voids.

In FIG. 6E residual material is provided over the top and bottom surfaces of the glass layer 625. In some instances, this overburden (e.g., portions of the liner 619, the seed layer 631, and the via 635) outside of the via opening 615 may be polished back. For example, a polishing or planarizing process, such as chemical mechanical planarization (CMP) may be used in some embodiment.

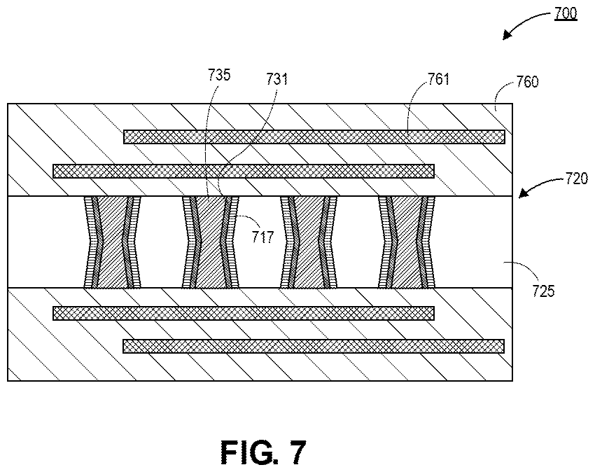

Referring now to FIG. 7, a cross-sectional illustration of a package substrate 700 is shown, in accordance with an embodiment. The package substrate 700 may comprise a glass core 720 that is sandwiched between buildup layers 760. The buildup layers 760 may comprise organic material, such as organic buildup film. One or more layers of buildup film can be laminated to provide the buildup layers 760 with a desired thickness. In an embodiment, electrically conductive features 761 (e.g., pads, traces, vias, etc.) may be embedded in the buildup layer 760.

In an embodiment, the glass core 720 may be similar to any of the glass core architectures described in greater detail herein. For example, the glass core 720 may include a glass layer 725 with vias 735 that pass through a thickness of the glass layer 725. In an embodiment, the vias 735 may be separated from the glass layer 725 by a liner 717 and a seed layer 731. The seed layer 731 may be an electroless seed layer 731. While not shown, some embodiments may also include a SAM between the liner 717 and the seed layer 731.

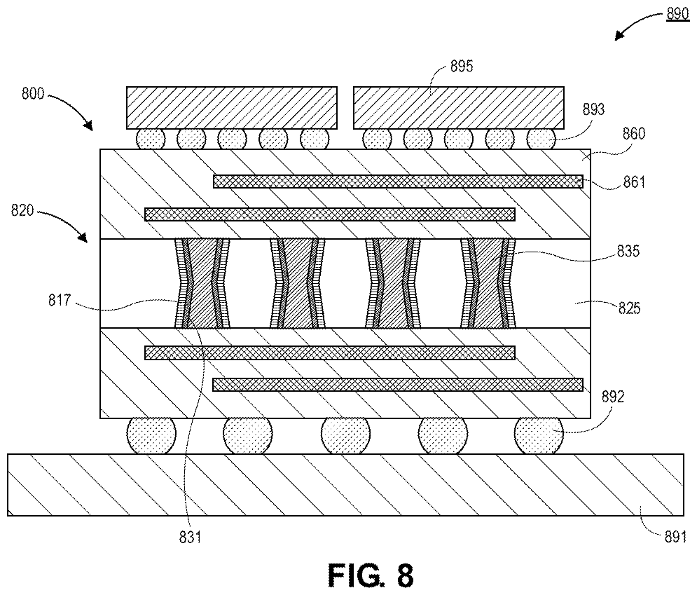

Referring now to FIG. 8, a cross-sectional illustration of an electronic system 890 is shown, in accordance with an additional embodiment. In an embodiment, the electronic system 890 may comprise a board 891, such as a printed circuit board (PCB). The board 891 may be coupled to a package substrate 800 by interconnects 892. The interconnects 892 may be a second level interconnect (SLI) architecture, such as solder balls, sockets, or the like.

In an embodiment, the package substrate 800 may be similar to the package substrate 700 described in greater detail above. For example, buildup layers 860 (with embedded electrically conductive features 861) may be provided above and below a glass core 820. The glass core 820 includes a glass layer 825 with vias 835. Liners 817 and seed layers 831 may separate the vias 835 from the glass layer 825.

In an embodiment one or more dies 895 may be coupled to the package substrate 800 by interconnects 893. The interconnects 893 may be a first level interconnect (FLI) architecture. For example, the interconnects 893 may comprise solder, copper bumps, hybrid bonding, or the like. In an embodiment, the dies 895 may include any type of die. For example, the dies 895 may be a central processing unit (CPU), a graphics processing unit (GPU), an XPU, a communications die, a memory die, or the like. In an embodiment, a bridge (either embedded in the buildup layers 860 or above the buildup layers 860) may be used to communicatively couple a pair of dies 895 together.

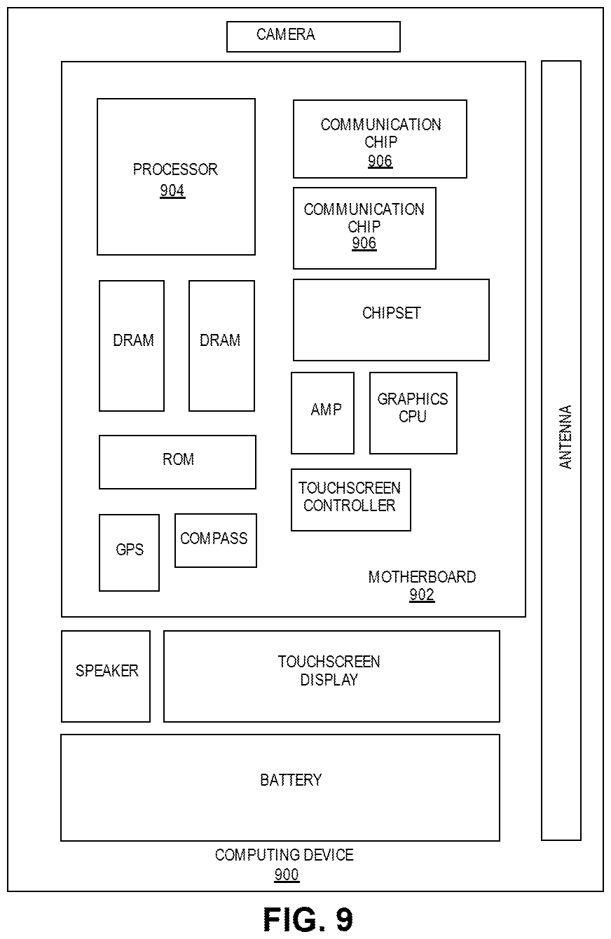

FIG. 9 illustrates a computing device 900 in accordance with one implementation of the disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the disclosure, the integrated circuit die of the processor may be part of an electronic package that includes a package substrate with a glass core that includes electrically conductive vias that are plated up from an electroless seed layer, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the disclosure, the integrated circuit die of the communication chip may be part of an electronic package that includes a package substrate with a glass core that includes electrically conductive vias that are plated up from an electroless seed layer, in accordance with embodiments described herein.

In an embodiment, the computing device 900 may be part of any apparatus. For example, the computing device may be part of a personal computer, a server, a mobile device, a tablet, an automobile, or the like. That is, the computing device 900 is not limited to being used for any particular type of system, and the computing device 900 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate, wherein the substrate is a solid glass layer; an opening through a thickness of the substrate; a liner with a first surface on a sidewall of the opening and a second surface facing away from the sidewall of the opening, wherein the liner comprises: a matrix; filler particles in the matrix; and a plurality of cavities into the second surface of the liner; and a via in the opening, wherein the via is electrically conductive.

Example 2: the apparatus of Example 1, wherein the cavities have a substantially circular segment shape.

Example 3: the apparatus of Example 2, wherein an arc of the circular segment shape is part of a circle that has a diameter that is within approximately 50% of an average diameter of the filler particles.

Example 4: the apparatus of Examples 1-3, wherein the cavities have an average opening diameter that is between approximately 20 nm and approximately 5 μm.

Example 5: the apparatus of Examples 1-4, wherein the via comprises a seed layer and a bulk layer, wherein the seed layer is between the liner and the bulk layer.

Example 6: the apparatus of Example 5, wherein the seed layer comprises palladium.

Example 7: the apparatus of Example 5 or Example 6, wherein the seed layer is an electroless seed layer comprising copper.

Example 8: an apparatus, comprising: a substrate, wherein the substrate is a solid glass layer; an opening through a thickness of the substrate; a liner on a sidewall of the opening; a self-assembled monolayer (SAM) over the liner; a seed layer on the SAM; and a via in the opening and in contact with the seed layer.

Example 9: the apparatus of Example 8, wherein the SAM comprises oxygen, silicon, carbon, and a reactive group.

Example 10: the apparatus of Example 9, wherein the reactive group comprises one or more of: sulfur and hydrogen; sulfur, oxygen, and hydrogen; nitrogen; nitrogen and hydrogen; carbon and nitrogen; and oxygen, carbon, and hydrogen.

Example 11: the apparatus of Example 9 or Example 10, wherein the reactive group comprises one or more of: SH, SO₃H, N₃, NH₂, CN, OCH₃, COOCH₃, and COOH.

Example 12: the apparatus of Examples 8-11, wherein the seed layer is an electroless seed layer.

Example 13: the apparatus of Example 12, wherein the seed layer comprises palladium and copper.

Example 14: an apparatus, comprising: a substrate, wherein the substrate is a solid glass layer; an opening through a thickness of the substrate; a liner on a sidewall of the opening, wherein the liner comprises an organic dielectric material with terminations comprising nitrogen and hydrogen; and a via in the opening over the liner.

Example 15: the apparatus of Example 14, wherein the liner comprises polyethylenimine (PEI).

Example 16: the apparatus of Example 14 or Example 15, wherein the via comprises a seed layer and a bulk layer, wherein the seed layer is between the bulk layer and the liner.

Example 17: the apparatus of Example 16, wherein the seed layer comprises palladium and copper.

Example 18: the apparatus of Example 16 or Example 17, wherein the seed layer is an electroless seed layer.

Example 19: the apparatus of Examples 14-18, wherein the liner is a cationic material.

Example 20: the apparatus of Example 19, wherein the substrate is negatively charged, and wherein an electrostatic interaction mechanically couples the liner to the substrate.

What is claimed is:

1. An apparatus, comprising:
a substrate, wherein the substrate is a solid glass layer;
an opening through a thickness of the substrate;
a liner with a first surface on a sidewall of the opening and a second surface facing away from the sidewall of the opening, wherein the liner comprises:
a matrix;
filler particles in the matrix; and
a plurality of cavities into the second surface of the liner; and
a via in the opening, wherein the via is electrically conductive.

2. The apparatus of claim 1, wherein the cavities have a substantially circular segment shape.

3. The apparatus of claim 2, wherein an arc of the circular segment shape is part of a circle that has a diameter that is within approximately 50% of an average diameter of the filler particles.

4. The apparatus of claim 2, wherein the cavities have an average opening diameter that is between approximately 20 nm and approximately 5 μm.

5. The apparatus of claim 1, wherein the via comprises a seed layer and a bulk layer, wherein the seed layer is between the liner and the bulk layer.

6. The apparatus of claim 5, wherein the seed layer comprises palladium.

7. The apparatus of claim 5, wherein the seed layer is an electroless seed layer comprising copper.

8. An apparatus, comprising:
a substrate, wherein the substrate is a solid glass layer;
an opening through a thickness of the substrate;
a liner on a sidewall of the opening;
a self-assembled monolayer (SAM) over the liner;
a seed layer on the SAM; and
a via in the opening and in contact with the seed layer.

9. The apparatus of claim 8, wherein the SAM comprises oxygen, silicon, carbon, and a reactive group.

10. The apparatus of claim 9, wherein the reactive group comprises one or more of: sulfur and hydrogen; sulfur, oxygen, and hydrogen; nitrogen; nitrogen and hydrogen; carbon and nitrogen; and oxygen, carbon, and hydrogen.

11. The apparatus of claim 9, wherein the reactive group comprises one or more of: SH, SO₃H, N₃, NH₂, CN, OCH₃, COOCH₃, and COOH.

12. The apparatus of claim 8, wherein the seed layer is an electroless seed layer.

13. The apparatus of claim 12, wherein the seed layer comprises palladium and copper.

14. An apparatus, comprising:
a substrate, wherein the substrate is a solid glass layer;
an opening through a thickness of the substrate;
a liner on a sidewall of the opening, wherein the liner comprises an organic dielectric material with terminations comprising nitrogen and hydrogen; and
a via in the opening over the liner.

15. The apparatus of claim 14, wherein the liner comprises polyethylenimine (PEI).

16. The apparatus of claim 14, wherein the via comprises a seed layer and a bulk layer, wherein the seed layer is between the bulk layer and the liner.

17. The apparatus of claim 16, wherein the seed layer comprises palladium and copper.

18. The apparatus of claim 16, wherein the seed layer is an electroless seed layer.

19. The apparatus of claim 14, wherein the liner is a cationic material.

20. The apparatus of claim 19, wherein the substrate is negatively charged, and wherein an electrostatic interaction mechanically couples the liner to the substrate.
